(19) United States
(12) Patent Application Publication
(10) Pub. No.: US 2010/0148147 A1
(43) Pub. Date: Jun. 17, 2010

(54) MONOLITHIC WHITE AND FULL-COLOR LIGHT EMITTING DIODES USING SELECTIVE AREA GROWTH

(75) Inventors: David P. Bour, Cupertino, CA (US); Christopher L. Chua, San Jose, CA (US); Noble M. Johnson, Menlo Park, CA (US)

Correspondence Address: PARC-XEROX/BSTZ;BLAKELY SOKOLOFF TAYLOR & ZAFMAN LLP, 1279 Oakmead Parkway, Sunnyvale, CA, 94085-4040, US

(73) Assignee: Palo Alto Research Center Incorporated, Palo Alto, CA (US)

(21) Appl. No.: 12/337,580

(22) Filed: Dec. 17, 2008

(51) Int. Cl. H01L 21/20; H01L 33/00

(52) U.S. Cl. 257/13; 438/35; 257/E21.09; 257/E33.008

(57) ABSTRACT

An embodiment is a method and apparatus for a white or full-color light-emitting diode. A first mask having a first pattern is applied over surface of an n-type layer. A first active region is grown selectively and including single or multiple quantum wells (QWs) of a first active color to cause a first wavelength shift in a first vicinity area around the first pattern. The first wavelength shift results in an emission of a first desired color according to the first pattern.

### TECHNICAL FIELD

The presently disclosed embodiments are directed to the field of optics, and more specifically, to light-emitting diodes.

### BACKGROUND

There has been considerable effort devoted toward development of nitride semiconductor light-emitting diodes (LEDs) for efficient solid-state lighting (SSL) and for full-color displays.

In the case of SSL, white light is generated by a blue LED through phosphor conversion of blue light into yellow; and this combination of blue and yellow appears white. Accordingly, the LED package typically includes a phosphor element which absorbs some of the blue emission from the nitride LED, and re-emits at yellow wavelengths. In order for the white emission to appear uniform over all viewing angles, the phosphor is distributed very uniformly. Inkjet printing and spin-on deposition technologies have been developed for phosphor application. Likewise, direct generation (phosphor-free) of white light has been demonstrated for chirped-quantum-well (QW) structures, for which the LED active region contains several QWs of different composition and thickness, each designed to emit at a wavelength whose combination appears white. Similarly, the multiple emission wavelengths may be accomplished by stacking two LED structures and placing a tunnel junction between them.

### SUMMARY

One disclosed feature of the embodiments is a method and apparatus for a white or full-color light-emitting diode. A first mask having a first pattern is applied over surface of an n-type layer. A first active region is grown selectively and including single or multiple quantum wells (QWs) of a first active color to cause a first wavelength shift in a first vicinity area around the first pattern. The first wavelength shift results in an emission of a first desired color according to the first pattern.

One disclosed feature of the embodiments is a white or full-color light-emitting diode. An n-type layer deposited on a substrate. A first active region selectively grown on the n-type layer. A first vicinity area in the first active region has a first wavelength shift with respect to a first color around a first pattern defined by a first mask. The first mask causes a selective area growth in the first active region resulting in thicker single or multiple quantum wells (QWs) of the first color. The thicker single or multiple QWs cause the first wavelength shift. The first wavelength shift results in an emission of a first desired color according to the first pattern.

One disclosed feature of the embodiments is a white or full-color light-emitting diode. A first active region is grown on an n-type layer. A first vicinity area in the first active region has a first wavelength shift with respect to a first color around a first pattern defined by a first mask. The first mask causes a selective area growth in the first active region resulting in thicker single or multiple quantum wells (QWs) of the first color. The thicker single or multiple QWs cause the first wavelength shift. The first wavelength shift results in an emission of a first desired color according to the first pattern.

### BRIEF DESCRIPTION OF THE DRAWINGS

Embodiments may best be understood by referring to the following description and accompanying drawings that are used to illustrate various embodiments. In the drawings.

FIG. 1 is a diagram illustrating a cross section view of an LED structure according to one embodiment.

FIG. 2 is a diagram illustrating a top view of the LED structure according to one embodiment.

FIG. 3 is a diagram illustrating a pattern with diamond shapes arranged in high duty factor according to one embodiment.

FIG. 4 is a diagram illustrating a pattern with diamond shapes arranged in low duty factor according to one embodiment.

FIG. 5 is a diagram illustrating a pattern with stripe shapes arranged in high duty factor according to one embodiment.

FIG. 6 is a diagram illustrating a pattern with stripe shapes arranged in low duty factor according to one embodiment.

FIG. 7 is a diagram illustrating a pattern with ring shapes according to one embodiment.

FIG. 8 is a diagram illustrating a pattern with concentric rings shapes according to one embodiment.

FIG. 9 is a diagram illustrating a pattern with polygon with ring shapes according to one embodiment.

FIG. 10 is a diagram illustrating a pattern with stripe shapes with gradual widths and inter-distances according to one embodiment.

FIG. 11 is a diagram illustrating a top view of the LED structure in the first fabrication phase according to one embodiment.

FIG. 12 is a diagram illustrating a cross section view of the LED structure in the first fabrication phase according to one embodiment.

FIG. 13 is a diagram illustrating a top view of the LED structure in the second fabrication phase according to one embodiment.

FIG. 14 is a diagram illustrating a cross section view of the LED structure in the second fabrication phase according to one embodiment.

FIG. 15 is a diagram illustrating a top view of the LED structure in the third fabrication phase according to one embodiment.

FIG. 16 is a diagram illustrating a cross section view of the LED structure in the third fabrication phase according to one embodiment.

FIG. 17 is a diagram illustrating a top view of the LED structure in the fourth fabrication phase according to one embodiment.

FIG. 18 is a diagram illustrating a cross section view of the LED structure in the fourth fabrication phase according to one embodiment.

FIG. 19 is a diagram illustrating a top view of the LED structure in the fifth fabrication phase according to one embodiment.

FIG. 20 is a diagram illustrating a cross section view of the LED structure in the fifth fabrication phase according to one embodiment.

FIG. 21 is a diagram illustrating a top view of the LED structure in the sixth fabrication phase according to one embodiment.

FIG. 22 is a diagram illustrating a cross section view of the LED structure in the sixth fabrication phase according to one embodiment.

FIG. 23 is a flowchart illustrating a process to form an LED using SAG according to one embodiment.

FIG. 24 is a flowchart illustrating a process to fabricate the second SAG region according to one embodiment.

### DETAILED DESCRIPTION

One disclosed feature of the embodiments is a method and apparatus for a white or full-color light-emitting diode. A first mask having a first pattern is applied over surface of an n-type layer. A first active region is grown selectively and including single or multiple quantum wells (QWs) of a first active color to cause a first wavelength shift in a first vicinity area around the first pattern. The first wavelength shift results in an emission of a first desired color according to the first pattern.

One disclosed feature of the embodiments is a white or full-color light-emitting diode. An n-type layer deposited on a substrate. A first active region selectively grown on the n-type layer. A first vicinity area in the first active region has a first wavelength shift with respect to a first color around a first pattern defined by a first mask. The first mask causes a selective area growth in the first active region resulting in thicker single or multiple quantum wells (QWs) of the first color. The thicker single or multiple QWs cause the first wavelength shift. The first wavelength shift results in an emission of a first desired color according to the first pattern.

One disclosed feature of the embodiments is a white or full-color light-emitting diode. A first active region is grown on an n-type layer. A first vicinity area in the first active region has a first wavelength shift with respect to a first color around a first pattern defined by a first mask. The first mask causes a selective area growth in the first active region resulting in thicker single or multiple quantum wells (QWs) of the first color. The thicker single or multiple QWs cause the first wavelength shift. The first wavelength shift results in an emission of a first desired color according to the first pattern.

One disclosed feature of the embodiments may be described as a process which is usually depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed. A process may correspond to a method, a program, a procedure, a method of manufacturing or fabrication, etc. One embodiment may be described by a schematic drawing depicting a physical structure. It is understood that the schematic drawing illustrates the basic concept and may not be scaled or depict the structure in exact proportions.

One disclosed feature of the embodiments is a method and apparatus to fabricate a monolithic LED to emit white or full color. The technique uses selective area growth (SAG) with a mask pattern to cause growth rate enhancement, leading to a wavelength shift in a vicinity area around the mask pattern. The wavelength shift in the region results in an emission of a desired color according to the pattern. By selecting a proper pattern with a number of shapes arranged with a suitable duty factor, the range of wavelength shift may be varied to produce a light emission of any desired color in the visible spectrum.

The mask size and placement may be optimized to utilize the growth rate enhancement associated with SAG to realize a range of InGaN QW thickness and composition across the LED structure. During SAG, nucleation does not occur on the dielectric mask. Surface species that would normally contribute to growth on the masked region instead evaporate off the mask. Subsequently, through gas phase diffusion, these species migrate to the unmasked regions where nucleation and growth is permitted. The mask therefore serves as an effective reservoir of additional species which contribute to an enhanced growth rate in the vicinity of the mask. The enhancement is greater for large mask areas; and likewise the enhancement is greatest near the mask edges. The characteristic distance over which the growth rate decays to its normal (unmasked) value represents the mean gas phase diffusion distance.

When InGaN QWs are grown selectively around dielectric masks, this growth rate enhancement translates into a greater QW thickness, and also higher indium content (since the In alloy composition is enhanced with the growth rate increase) in the vicinity of the mask. Consequently, the wavelength will be shifted longer with respect to the field region that is beyond the horizon of the mask. The emission wavelength of an InGaN QW LED with such a selectively-grown active region will therefore have a range of values. For example, if the wavelength is adjusted to be blue (λ˜460 nm) in the field away from the mask edges, the material deposited closer to the mask may have an emission wavelength shifted toward red/yellow wavelengths. The range of wavelength values may depend on the mask shape and size; and the relative areas for the different wavelengths may be controlled through the duty factor of the mask pattern.

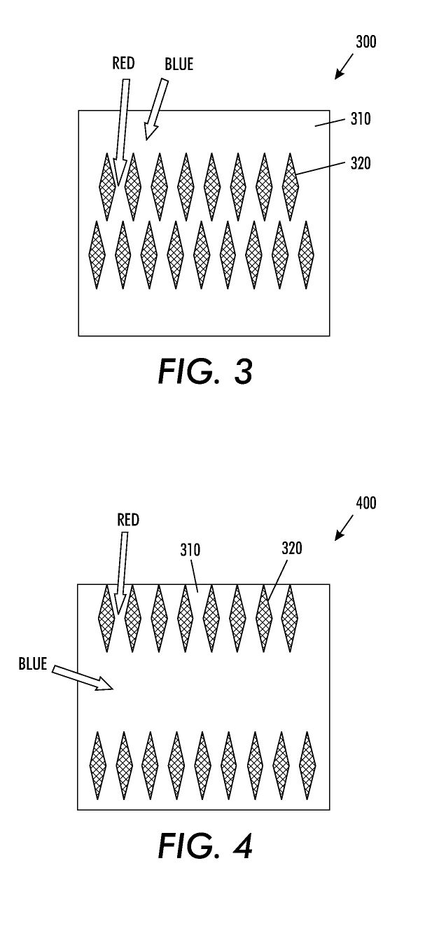

A mask has a mask pattern that may have a number of shapes arranged according to a duty factor. The duty factor refers to the repetition rate of the shapes. A high repetition rate, or a high duty factor, corresponds to closely spaced shapes. A high duty factor increases proportion of a higher wavelength emission or decreases proportion of a lower wavelength emission. A low repetition rate, or a low duty factor, corresponds to sparsely spaced shapes. A low duty factor decreases proportion of a higher wavelength emission or increases proportion of a lower wavelength emission. The regions below the shapes of the mask pattern are defined for SAG. For example, in the field, the emission wavelength may be blue as determined by the QW parameters, while in the vicinity of the mask, the SAG enhancements may shift the emission wavelength toward red. When the entire LED structure is subject to forward bias conditions, the overall emission spectrum correspond to a superposition of the emission from all areas. A white emission may be obtained by optimizing the emission areas of the various colors. This may be accomplished by adjusting the duty factor of the mask pattern. For instance, the duty factor of the masking may be increased to increase the proportion of material with red-shifted emission; or it may be reduced to increase the proportion of blue-emitting material. In this manner, the emission spectrum may be adjusted to achieve the desired white value. Various mask patterns with high and low duty factors are shown from FIG. 3 through FIG. 10.

The individual colors may also be separately addressed to produce true white or full color. Multiple p-electrodes may be formed along the surface of the LED structure. When properly registered with respect to the underlying SAG mask, each electrode may be used to control and generate an individual color. When a proper bias current is applied to all contacts, the emission is spectrally broadband, corresponding to any desired color in the visible spectrum. In addition, multiple selective area growth phases may also be employed to achieve a wide range of colors over an LED device.

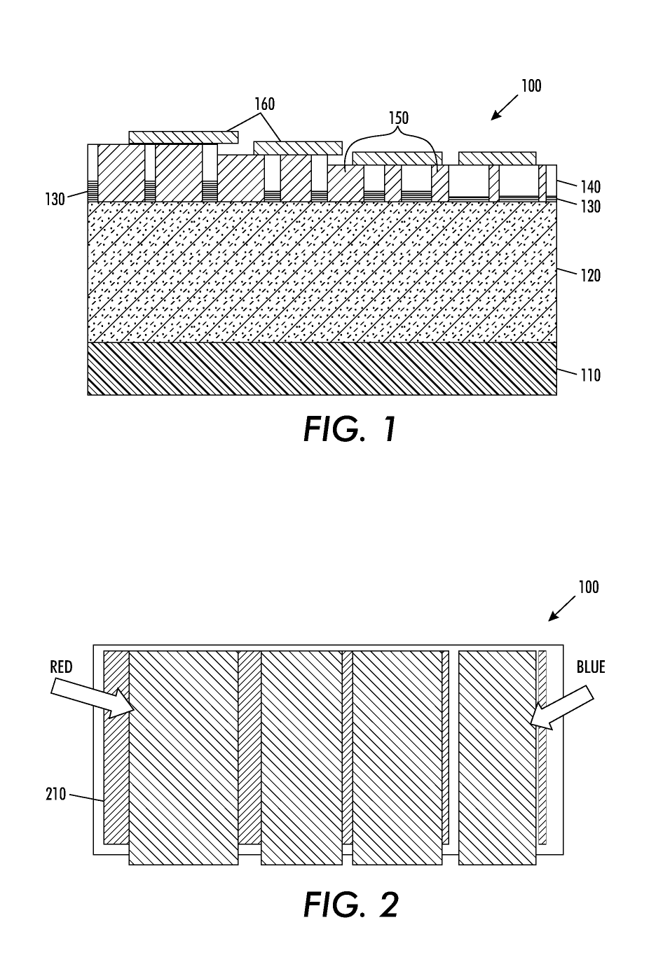

FIG. 1 is a diagram illustrating a cross section view of an LED structure 100 according to one embodiment. The LED structure 100 includes a substrate 110, an n-type layer 120, an active region 130 having multiple QWs, a p-type layer 140, dielectric layers 150, and p-electrodes 160. The LED structure 100 may includes more or less components than the above. For example, it may have a single p-electrode.

The substrate 110 may be any suitable substrate. It may be made of sapphire (Al₂O₃), zinc oxide (ZnO), or silicon carbide (SiC). Typically, the substrate 110 has low lattice mismatch constant (e.g., approximately 3% to 14%) and is transparent to visible light.

The n-type layer 120 is deposited on the substrate 110. It is used together with the p-type layer 160 to form the p-n junction for the diode operation in the LED. The n-type layer 120 may be made of suitable material. In one embodiment, it is made of gallium nitride (GaN) doped with Silicon. It may be deposited on the substrate 110 by a suitable deposition method such as the metal organic chemical vapor deposition (MOCVD). The thickness of the n-type layer 120 may be above the critical thickness (e.g., 2 μm) to reduce strain and defects at the interface with the substrate.

The active region 130 is between the n-type layer 120 and the p-type layer 160. It has single or multiple QWs of a first color formed on the n-type layer. In one embodiment, the single or multiple QWs may correspond to a wavelength ranging from 400 nm to 480 nm. In one embodiment, the single or multiple QWs are blue-emitting QWs. They may include alternating layers of a number of undoped InₓGa₁₋ₓN QWs with appropriate composition (e.g., In_{0.15}Ga_{0.85}N) and GaN barriers. The blue-emitting InₓGa₁₋ₓN QWs may have an appropriate thickness (e.g., 2 to 3 nm). The GaN barrier layer may have an appropriate thickness (e.g., 5 to 15 nm).

The single or multiple QWs may be grown selectively around dielectric masks or a mask pattern. Due to the growth rate enhancement, the QWs may have varying thickness as they move across the length of the LED structure. This may lead to a corresponding wavelength shift across the length of the LED structure. The QWs may be separated by the dielectrics layers 150 according to a mask pattern. In one embodiment, the mask pattern includes stripes that are separated by distances corresponding to the p-electrodes 160.

The p-type layer 140 is deposited on the active region 130. There may be another p-type layer between the active region 130 and the p-type layer 40. The p-type layer 140 may be made of GaN doped with Magnesium (Mg). It may be activated with rapid thermal annealing (RTA) for removal of hydrogen atoms.

The dielectrics layers 150 may be any suitable dielectric material. They may be deposited over the n-type layer 120 and patterned before the multiple QWs are grown. The single or multiple QWs are grown or deposited around the dielectrics layers 150.

The p-type electrodes 160 may be any suitable electrically conductive material. They may be made of thin metal, aluminum, gold, chromium, indium tin oxide, conducting polymer such as poly(3,4-ethylenedioxythiophene):poly(4-styrenesulfonate) (PEDOT:PSS). They may be deposited using a suitable deposition process such as printing.

The p-type electrodes 160 and a common n-type electrode (not shown) provide control and generation of individual emissions of colors corresponding to the wavelength shift. The individual colors may then be separately addressed and controlled. When the individual currents are adjusted, they provide generation of true white or full-color light output. When there is a single p-type electrode 160, the LED structure 100 may still generate true white or full color light output by using an appropriate mask pattern with multiple shapes arranged according to a duty factor as discussed above.

FIG. 2 is a diagram illustrating a top view of the LED structure 100 according to one embodiment. The top view shows a mask pattern 210 that is used to cause selective area growth of the multiple QWs in the active region 130 as shown in FIG. 1.

The mask pattern 210 may be formed by an appropriate mask made of suitable material such as SiO₂. As illustrated in FIG. 2, the mask pattern 210 includes a number of stripes which vary in width and duty factor across the length of the LED from right to left. The stripes are narrow and located far apart on the right-hand side. Under this condition, the QW growth may be adjusted for blue-emission in this masked region. Toward the left-hand side, the mask stripes become wider and more closely spaced, causing a local growth rate enhancement. Accordingly, the emission from the left-hand side may be red-shifted with respect to the right-hand side. Under the proper choice of growth condition and mask geometry, the emission may be shifted from blue to orange/red across the LED structure 100, spanning the entire spectrum to create multiple individual colors corresponding to the p-electrodes 160.

As discussed above, the above construction may have a single p-electrode. The result is a composite single color that may represent any true color including white within the visible spectrum. The generation of the color output depends on the mask pattern, its geometry, shapes, and duty factor.

FIG. 3 is a diagram illustrating a pattern 300 with diamond shapes arranged in high duty factor according to one embodiment. The pattern 300 includes a number of shapes 310. The shapes 310 are shown above a GaN surface 310. In the embodiment shown in FIG. 3, the shapes are diamond shapes arranged in a high duty factor. As discussed above, the red-emission regions correspond to the closely spaced shapes while the blue-emission regions correspond to the sparsely spaced shapes. Accordingly, the pattern 300 having a high duty factor may correspond to more red emission.

FIG. 4 is a diagram illustrating a pattern 400 with diamond shapes arranged in low duty factor according to one embodiment. The pattern 400 includes diamond shapes as the pattern 300 in FIG. 3 except that the pattern 400 has a low duty factor. Compared to the pattern 300, the diamond shapes in the pattern 400 are more sparsely spaced. Accordingly, the pattern 400 having a low duty factor may correspond to more blue emission.

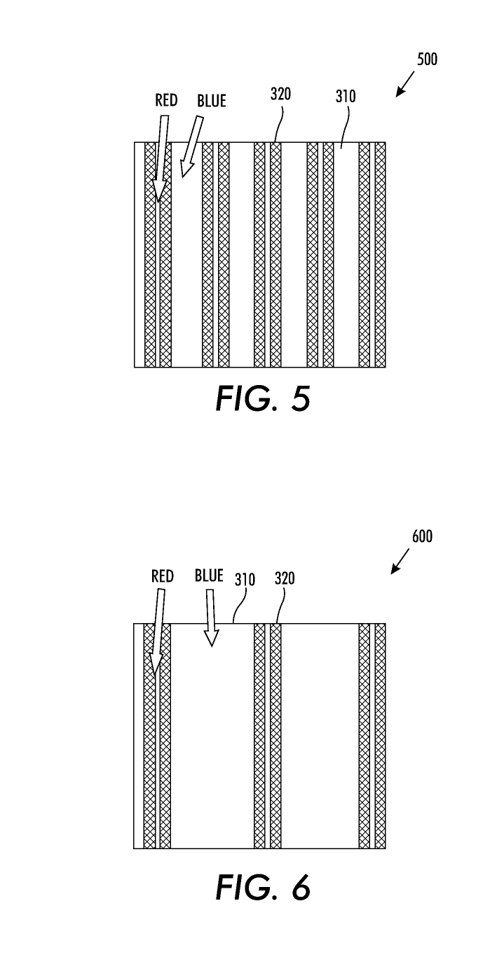

FIG. 5 is a diagram illustrating a pattern 500 with stripe shapes arranged in high duty factor according to one embodiment. As in FIGS. 3 and 4, the pattern 500 includes a number of shapes 320 above the GaN surface 310. The shapes 320 are narrow stripes formed in pairs. The gap between the stripes in each pair is narrow, but there are large gaps between the pairs. In the field, far from the mask pairs, the emission wavelength is blue. The SAG enhancements in the narrow center of the mask-stripe pair shifts the emission wavelength toward red, with the magnitude of the shift defined by the width of the mask and narrow opening, along with the growth conditions. The pattern 500 has a high duty factor where the pairs of stripes are closely spaced. The proportion of material with red-shifted emission is increased. Accordingly, the pattern 500 having a high duty factor may correspond to more red emission.

FIG. 6 is a diagram illustrating a pattern 600 with stripe shapes arranged in low duty factor according to one embodiment. The pattern 600 is similar to the pattern 500 except that the duty factor is low. The pairs of stripes are sparsely spaced. The proportion of material with blue-shifted emission is increased. Accordingly, the pattern 600 having a low duty factor may correspond to more blue emission.

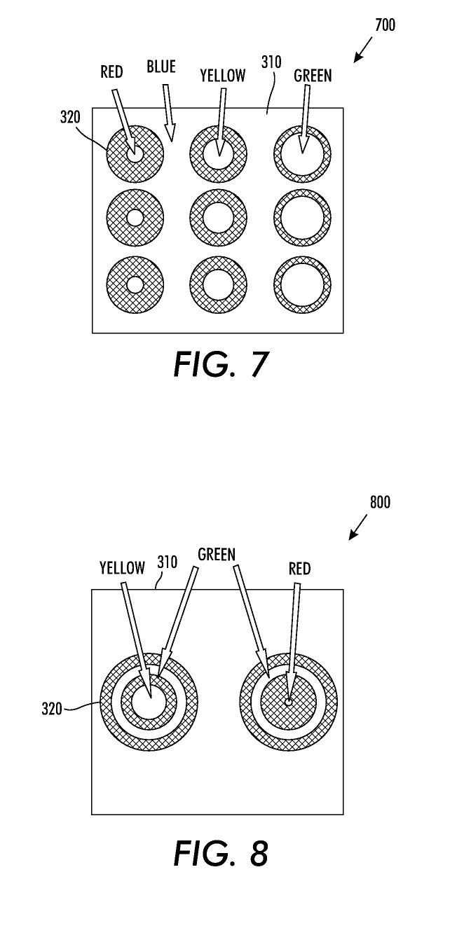

FIG. 7 is a diagram illustrating a pattern 700 with ring shapes according to one embodiment. The pattern 700 includes a number of ring shapes 320 above the GaN surface 310. The ring width and the size of the ring center may be adjusted to achieve the desired wavelength shift; and these parameters may be varied across the LED structure to yield a range of emission wavelengths, for producing a true broadband white. The fill factor of the mask may also be optimized to produce the proper mix of the emission wavelengths, for example to achieve the desired color temperature. In the field, the emission wavelength is blue while the SAG enhancements in the core of the ring shift the emission wavelength toward red according to the size of the center opening. If the size of the center opening is small, the emission wavelength becomes more red. As the size of the center opening increases, the wavelength shifts toward green. A medium center opening size may correspond to a yellow wavelength. By adjusting the size of the center opening, the wavelength may be shifted to any wavelength in the visible spectrum, leading to generation of any desired color.

FIG. 8 is a diagram illustrating a pattern 800 with concentric rings shapes according to one embodiment. The pattern 800 includes shapes of concentric rings 320 above the GaN surface 310. The size of the center opening and the gap between the rings may be adjusted to produce a range of wavelengths. For example, as the size of the center opening is small, the wavelength is shifted to red emission. As it increases in size, the wavelength is shifted toward green. For a medium size of the center opening, the wavelength is shifted toward yellow. Similarly, the size of the gap between the rings also causes the local wavelength shift. As this gap is small, the wavelength is shifted toward red. When this gap is medium, the wavelength is shifted toward yellow. When this gap is large as shown in the Figure, the wavelength is shifted toward green. By adjusting the size of the center opening and the gap between the rings, the wavelength may be shifted to any wavelength in the visible spectrum, leading to generation of any desired color.

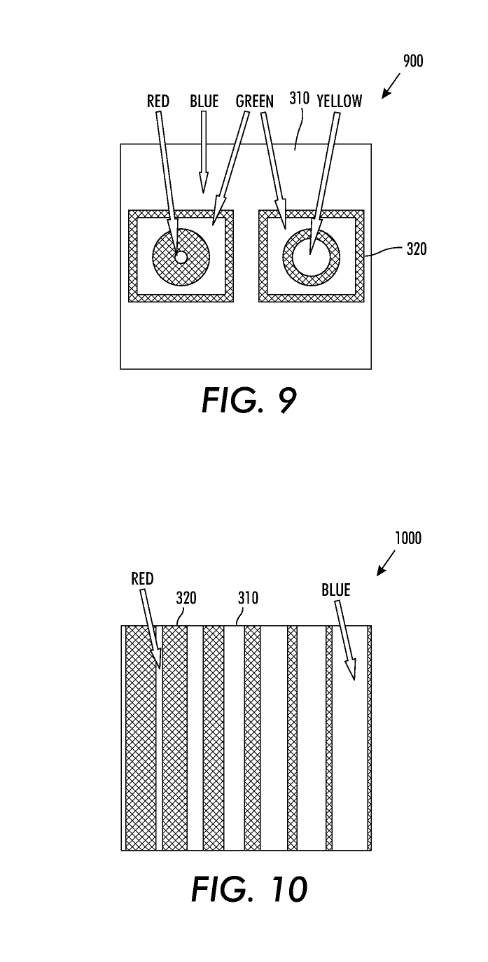

FIG. 9 is a diagram illustrating a pattern 900 with polygon with ring shapes according to one embodiment. The pattern 900 includes shapes of polygons containing a ring 320 above the GaN surface 310. The polygon may be any suitable polygon. In one embodiment, the polygon may be a square as shown in FIG. 9. The ring inside the square may have a center opening. By adjusting the size of the ring and the size of the center opening of the ring, a variety of wavelength shifts may be realized. For example, when the center opening of the ring is small, the wavelength is shifted toward red; when this center opening is medium, the wavelength is shifted toward yellow. Similarly, when the space between the square and the inside ring is small, the wavelength is shifted toward red. When this space is large as shown in the figure, the wavelength is shifted toward green.

FIG. 10 is a diagram illustrating a pattern 1000 with stripe shapes with gradual widths and inter-distances according to one embodiment. The pattern 1000 includes shapes of stripes 320 above the GaN surface 310. The stripes vary in width and duty factor across the length of the LED from right to left. The stripes are narrow and located far apart on the right-hand side. Under this condition, the QW growth may be adjusted for blue-emission in this masked region. Toward the left-hand side, the mask stripes become wider and more closely spaced, causing a local growth rate enhancement. Accordingly, the emission from the left-hand side may be red-shifted with respect to the right-hand side. Under the proper choice of growth condition and mask geometry, the emission may be shifted from blue to orange/red across the LED structure spanning the entire spectrum to create any desired color in the visible spectrum.

The patterns shown from FIGS. 3 through 10 are for illustrative purposes only. It is anticipated that any suitable patterns may be employed.

The LED structure may be fabricated by applying the mask having the desired pattern as discussed above. When the mask is applied, the active region having multiple QWs may be grown selectively around the mask, causing a wavelength shift in the vicinity area around the mask. The process may be performed for one phase of SAG or multiple phases of SAG to achieve a wide range of colors over the LED structure.

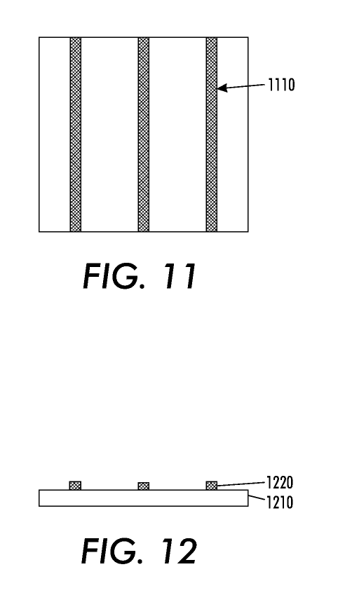

FIG. 11 is a diagram illustrating a top view of the LED structure in the first fabrication phase according to one embodiment. The top view shows a first mask with the first mask pattern 1110. In this illustrative example, the first mask pattern 1110 includes a number of strips arranged with a low duty factor. As discussed above, any suitable mask pattern may be employed as in the examples shown from FIGS. 3 through 10. In the first phase of the fabrication process, the first mask pattern 1110 is applied over an n-type GaN surface.

FIG. 12 is a diagram illustrating a cross section view of the LED structure in the first fabrication phase according to one embodiment. The mask pattern 1110 is applied over the n-type GaN layer 1210. The pattern results in mask layers 1220 on the n-type GaN layer 1210.

FIG. 13 is a diagram illustrating a top view of the LED structure in the second fabrication phase according to one embodiment. In the second fabrication phase, an active region having single or multiple QWs is grown selectively around the first mask. A p-type layer is then deposited to form the p-n junction. If the single or multiple QWs are blue-emitting QWs, they are SAG shifted to a longer, green wavelength in the vicinity of the mask. The top view shows a first region 1310 that is wavelength shifted. The first region 1310 corresponds to a region having multiple QWs of a first wavelength, e.g., green wavelength.

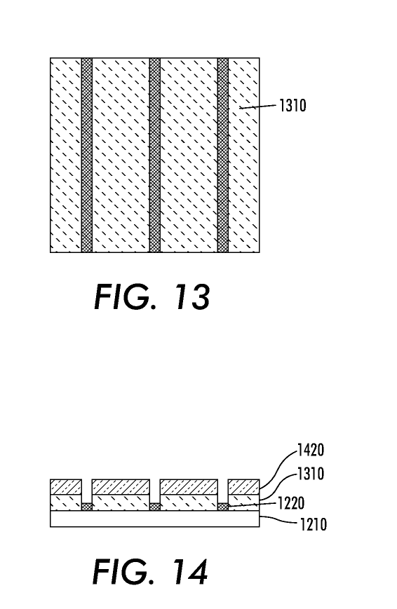

FIG. 14 is a diagram illustrating a cross section view of the LED structure in the second fabrication phase according to one embodiment. The cross section view shows the n-type GaN layer 1210, the mask layers 1220, the first region 1310, and the p-type GaN layer 1420.

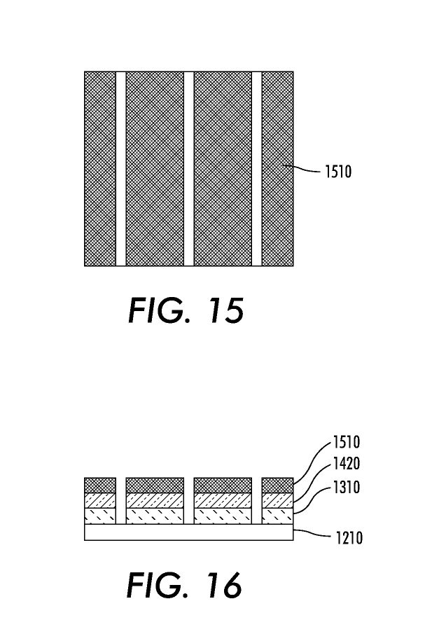

FIG. 15 is a diagram illustrating a top view of the LED structure in the third fabrication phase according to one embodiment. In the third fabrication phase, the first mask is removed. A second mask with a second mask pattern 1510 is applied. As shown, the second pattern 1510 is complementary to the first pattern 1110 shown in FIG. 11.

FIG. 16 is a diagram illustrating a cross section view of the LED structure in the third fabrication phase according to one embodiment. The cross section view shows the n-type GaN layer 1210, the mask layers 1220, the first region 1310, the p-type GaN layer 1420, and the second mask layer 1510.

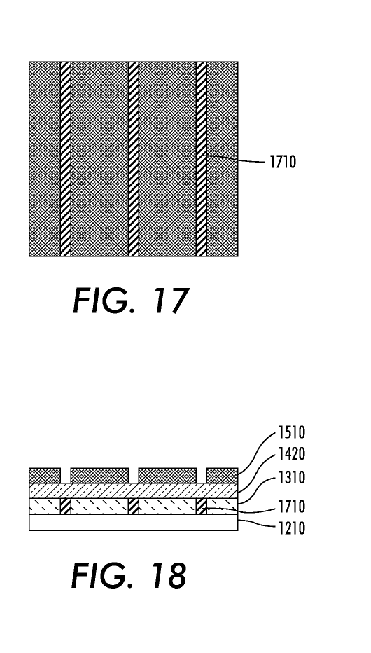

FIG. 17 is a diagram illustrating a top view of the LED structure in the fourth fabrication phase according to one embodiment. In the fourth fabrication phase, a second region 1710 is selective grown using the second mask pattern 1510. The second region 1710 corresponds to a region having multiple QWs of a second wavelength, e.g., yellow-red wavelength.

FIG. 18 is a diagram illustrating a cross section view of the LED structure in the fourth fabrication phase according to one embodiment. The cross section view shows the n-type GaN layer 1210, the first region 1310, the p-type GaN layer 1420, the second mask layer 1510, and the second region 1710.

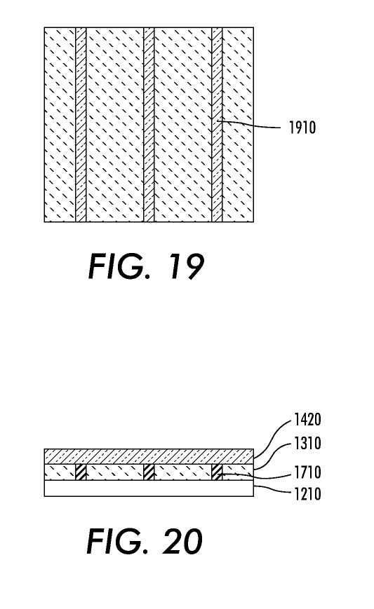

FIG. 19 is a diagram illustrating a top view of the LED structure in the fifth fabrication phase according to one embodiment. In the fifth fabrication phase, the second mask is removed, exposing the p-type GaN layer 1910.

FIG. 20 is a diagram illustrating a cross section view of the LED structure in the fifth fabrication phase according to one embodiment. The cross section view shows the n-type GaN layer 1210, the first region 1310, the p-type GaN layer 1420, and the second region 1710.

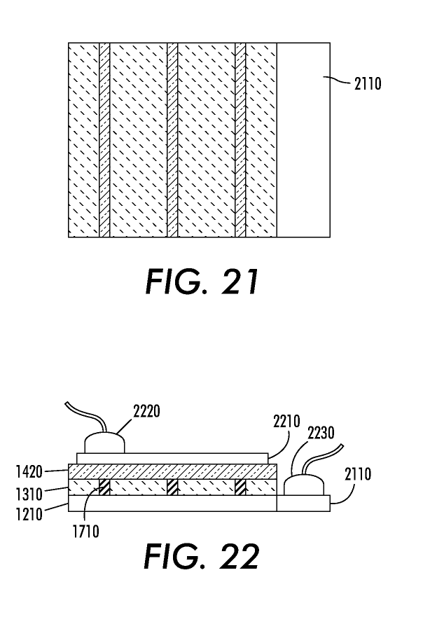

FIG. 21 is a diagram illustrating a top view of the LED structure in the sixth fabrication phase according to one embodiment. In the sixth fabrication phase, the LED fabrication is completed. A transparent p-electrode 2210 (shown in FIG. 22) is applied. An n-type electrode 2110 is added. A p-contact pad 2220 (shown in FIG. 22) is deposited on the p-electrode 2210. An n-contact pad 2230 (shown in FIG. 22) is deposited on the n-electrode 2110.

FIG. 22 is a diagram illustrating a cross section view of the LED structure in the sixth fabrication phase according to one embodiment. The cross section view shows the n-type GaN layer 1210, the first region 1310, the p-type GaN layer 1420, the second region 1710, the n-electrode 2110, the p-electrode 2210, the p-contact pad 2220, and the n-contact pad 2230.

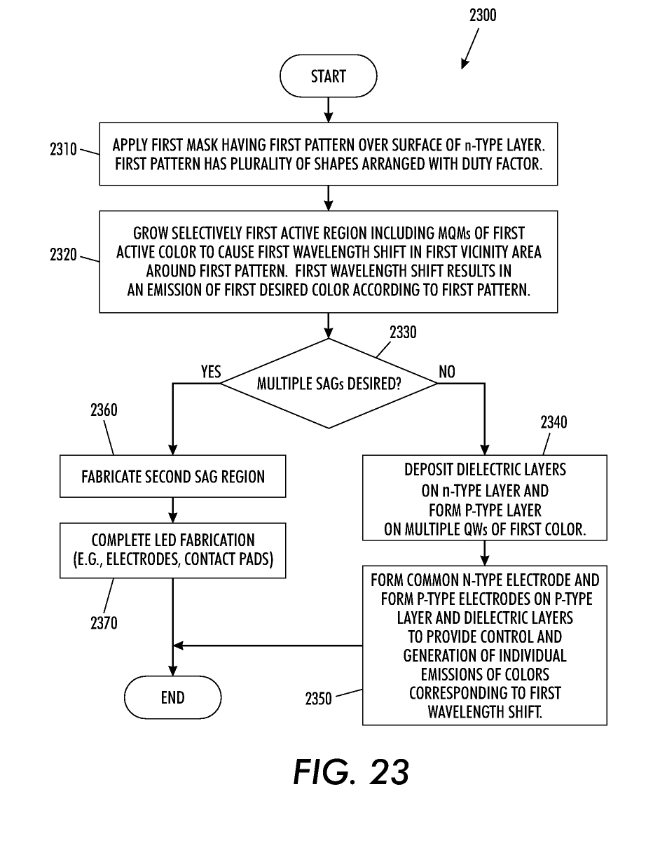

FIG. 23 is a flowchart illustrating a process 2300 to form an LED using SAG according to one embodiment.

Upon START, the process 2300 applies a first mask having a first pattern over surface of an n-type layer (Block 2310). The first pattern has a plurality of shapes arranged with a duty factor. Next, the process 2300 grows selectively a first active region including multiple QWs of a first active color to cause a first wavelength shift in a first vicinity area around the first pattern (Block 2320). The first wavelength shift results in an emission of a first desired color according to the first pattern.

Then, the process 2300 determines if a second SAG is desired (Block 2330). If not, the process 2300 deposits dielectric layers on the n-type layer and forms p-type layer on the multiple QWs of the first color (Block 2340). Next, the process 2300 forms a common n-type electrode and forming p-type electrodes on the p-type layer and the dielectric layers if there are individual blocks (Block 235). For individual color blocks, the p-type electrodes and the common n-type electrode providing control and generation of individual emissions of colors corresponding to the first wavelength shift. The process 2300 is then terminated.

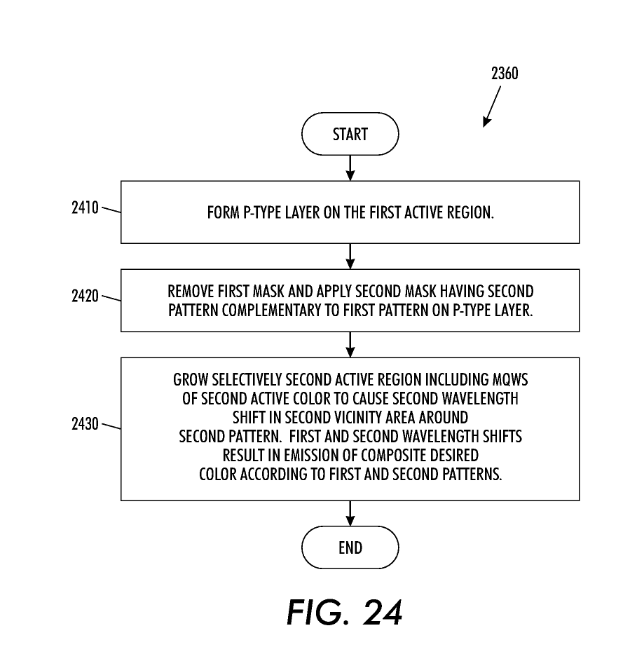

If a second SAG is desired, the process 2300 fabricates a second SAG region (Block 2360). The details of this operation are shown in FIG. 24. Then, the process 2300 completes the LED fabrication (Block 2370). This may include depositing electrodes and forming contact pads on the electrodes. The process 2300 is then terminated.

FIG. 24 is a flowchart illustrating the process 2360 shown in FIG. 23 to fabricate the second SAG region according to one embodiment.

Upon START, the process 2360 forms a p-type layer on the first active region (Block 2410). This may include depositing a layer of GaN doped with Mg. Next, the process 2360 removes the first mask and applies a second mask having a second pattern complementary to the first pattern on the p-type layer (Block 2420). Then, the process 2360 grows selectively a second active region including multiple QWs of a second active color to cause a second wavelength shift in a second vicinity area around the second pattern (Block 2430). The second wavelength shift and the first wavelength shift result in an emission of a composite desired color according to the first and second patterns.

It will be appreciated that various of the above-disclosed and other features and functions, or alternatives thereof, may be desirably combined into many other different systems or applications. Various presently unforeseen or unanticipated alternatives, modifications, variations, or improvements therein may be subsequently made by those skilled in the art which are also intended to be encompassed by the following claims.

What is claimed is:

1. A method comprising:
applying a first mask having a first pattern over surface of an n-type layer; and
growing selectively a first active region including single or multiple quantum wells (QWs) of a first active color to cause a first wavelength shift in a first vicinity area around the first pattern, the first wavelength shift resulting in an emission of a first desired color according to the first pattern.

2. The method of claim 1 further comprising:
forming a p-type layer on the first active region;
removing the first mask;
applying a second mask having a second pattern complementary to the first pattern on the p-type layer; and
growing selectively a second active region including multiple QWs of a second active color to cause a second wavelength shift in a second vicinity area around the second pattern, the second wavelength shift and the first wavelength shift resulting in an emission of a composite desired color according to the first and second patterns.

3. The method of claim 1 wherein the first pattern has a plurality of shapes arranged with a duty factor.

4. The method of claim 3 wherein the plurality of shapes have at least one of a diamond shape, a stripe shape, a disc shape, a ring shape, a concentric rings shape, a polygon shape, and a polygon with ring shape.

5. The method of claim 3 wherein a high duty factor increases proportion of a higher wavelength emission or decreases proportion of a lower wavelength emission.

6. The method of claim 3 wherein a low duty factor decreases proportion of a higher wavelength emission or increases proportion of a lower wavelength emission.

7. The method of claim 1 wherein the plurality of shapes includes stripes with varying widths.

8. The method of claim 1 wherein the first desired color is white or a full color.

9. The method of claim 1 wherein the first active color is blue.

10. The method of claim 1 further comprising:
depositing dielectric layers on the n-type layer;
forming p-type layer on the single or multiple QWs of the first color;
forming a common n-type electrode; and
forming p-type electrodes on the p-type layer and the dielectric layers, the p-type electrodes and the common n-type electrode providing control and generation of individual emissions of colors corresponding to the first wavelength shift.

11. An apparatus comprising:
a first active region grown on an n-type layer; and
a first vicinity area in the first active region having a first wavelength shift with respect to a first color around a first pattern defined by a first mask, the first mask causing selective area growth in the first active region resulting in thicker single or multiple quantum wells (QWs) of the first color, the thicker single or multiple QWs causing the first wavelength shift, the first wavelength shift resulting in an emission of a first desired color according to the first pattern.

12. The apparatus of claim 11 further comprising:
a p-type layer deposited on the first active region;
a second active region grown on an n-type layer and having multiple QWs of a second color; and
a second vicinity area having a second wavelength shift with respect to the second color around a second pattern defined by a second mask complementary to the first mask, the second wavelength shift and the first wavelength shift resulting in an emission of a composite desired color according to the first and second patterns.

13. The apparatus of claim 11 wherein the first pattern has a plurality of shapes arranged with a duty factor.

14. The apparatus of claim 13 wherein the plurality of shapes have at least one of a diamond shape, a stripe shape, a disc shape, a ring shape, a concentric rings shape, a polygon shape, and a polygon with ring shape.

15. The apparatus of claim 13 wherein a high duty factor increases proportion of a higher wavelength emission or decreases proportion of a lower wavelength emission.

16. The apparatus of claim 13 wherein a low duty factor decreases proportion of a higher wavelength emission or increases proportion of a lower wavelength emission.

17. The apparatus of claim 11 wherein the plurality of shapes includes stripes with varying widths.

18. The apparatus of claim 11 wherein the first desired color is white or a full color.

19. The apparatus of claim 11 wherein the first active color is blue.

20. The apparatus of claim 11 further comprising:
dielectric layers deposited between adjacent multiple QWs of the first color;
a p-type layer on the multiple QWs of the first color;
a common n-type electrode; and
a plurality of p-type electrodes on the p-type layer and the dielectric layers, the p-type electrodes and the common n-type electrode providing control and generation of individual emissions of colors corresponding to the first wavelength shift.

21. A light-emitting diode (LED) comprising:
a substrate;
an n-type layer deposited on the substrate;
a first active region grown on the n-type layer; and
a first vicinity area in the first active region having a first wavelength shift with respect to a first color around a first pattern defined by a first mask, the first mask causing selective area growth in the first active region resulting in thicker single or multiple quantum wells (QWs) of the first color, the thicker single or multiple QWs causing the first wavelength shift, the first wavelength shift resulting in an emission of a first desired color according to the first pattern.

22. The LED of claim 21 further comprising:
a p-type layer deposited on the first active region;
a second active region grown on an n-type layer and having multiple QWs of a second color; and
a second vicinity area having a second wavelength shift with respect to the second color around a second pattern defined by a second mask complementary to the first mask, the second wavelength shift and the first wavelength shift resulting in an emission of a composite desired color according to the first and second patterns.

23. The LED of claim 21 wherein the first pattern has a plurality of shapes arranged with a duty factor.

24. The LED of claim 23 wherein the plurality of shapes have at least one of a diamond shape, a stripe shape, a disc shape, a ring shape, a concentric rings shape, a polygon shape, and a polygon with ring shape.

25. The LED of claim 21 wherein the first desired color is white or a full color.
